(19) United States
(12) Patent Application Publication
(10) Pub. No.: US 2007/0057365 A1
(43) Pub. Date: Mar. 15, 2007

(54) Device for preventing low-melting-point heat-transfer medium from oxidization

(76) Inventor: Luk-Shan Wong, Yung Kang City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/223,996

(22) Filed: Sep. 13, 2005

(51) Int. Cl. H01L 23/34

(52) U.S. Cl. 257/712

(57) ABSTRACT

A device for preventing a low-melting point heat-transfer medium from oxidization is proposed. The device has a heat sink, a low-melting-point alloy, and an oxidization-proof layer. The low-melting-point alloy is disposed on the heat sink and serves as a heat-transfer medium to contact a heat source. The oxidization-proof layer is made of a condensable material and disposed on the heat sink. The oxidization-proof layer surrounds the low-melting-point alloy. The oxidization-proof layer can effectively prevent the low-melting-point alloy from invasion by ambient air by isolating the low-melting-point alloy from the ambient air. Hence, the oxidization of the low-melting-point alloy is prevented and the high heat-transfer efficiency of the low-melting-point alloy is kept.

### BACKGROUND OF THE INVENTION

1. Field of the Invention

The present invention is related to a device for preventing a low-melting point heat-transfer medium from oxidization, and more particularly, to a device that can prevent the low-melting point heat-transfer medium from contacting ambient air so as to prevent it from oxidization. In this way, a high heat-transfer efficiency of the low-melting point heat-transfer medium is kept.

2. Description of Related Art

With the rapid progress of computer industries, electronic heat sources, such as chips or central processing units (CPUs), have faster and faster processing speeds and produce more and more heat. In order to dissipate heat and maintain normal operations, the electronic heat source is usually attached to a heat-dissipating device having a larger heat-dissipating surface. The heat-dissipating device uses its heat-dissipating fins to dissipate heat. An example of a conventional heat-dissipating device is disclosed in TW Patent No. 562395 issued on Nov. 11, 2003.

In order to pass heat produced by the heat source to a heat-dissipating device, a thermal grease is applied between the heat source and the heat-dissipating device. Via the thermal grease, heat can be passed from the heat source to the heat-dissipating device and then be dissipated.

As described above, the thermal grease serves as a heat-transfer medium. However, the heat transfer coefficient of the thermal grease is very small, so the thermal grease is inefficient in heat transfer. Hence, heat generated by chips or CPUs usually cannot be passed to the heat-dissipating device effectively, resulting in a low overall heat dissipation efficiency.

To resolve this problem, an alloy with a low melting point is attached to the bottom of the heat-dissipating device and serves as a heat-transfer medium. Since the heat transfer coefficient of the alloy is larger, heat generated by the heat source can be effectively passed to the heat-dissipating device. Hence, the overall heat dissipation efficiency is higher.

The low-melting-point alloy mentioned above serves as a heat-transfer medium. If the low-melting-point alloy is coated on the bottom of the heat-dissipating device via a sprinkling process, some air bubbles are produced and stay inside the low-melting-point alloy. The heat-transfer efficiency is therefore degraded. This problem can be resolved by reducing the sprinkled alloy particles or using a sheet-shaping process.

However, the low-melting-point alloy mentioned above is disposed between the heat source and the heat-dissipating device. Once the temperature of the heat source is higher than the melting point of the alloy, the alloy melts and becomes a liquid. In this situation, the alloy stays in a flowing state and its outer edge directly contacts the ambient air. Thus, the ambient air easily invades the alloy, and oxidizes the alloy. This oxidation degrades the heat-transfer efficiency of the alloy.

### SUMMARY OF THE INVENTION

An objective of the present invention is to provide a device for preventing a low-melting point heat-transfer medium from oxidizing. In the present invention, an oxidization-proof layer is disposed on the bottom of the heat sink. The oxidization-proof layer surrounds the low-melting-point alloy, which is disposed between the heat sink and the heat source. The oxidization-proof layer can effectively prevent the low-melting-point alloy from invasion by ambient air by isolating the low-melting-point alloy from the ambient air. Hence, the oxidization of the low-melting-point alloy is prevented. By using the present invention, the high heat-transfer efficiency of the low-melting-point alloy is kept.

For achieving the objective above, the present invention provides a device for preventing a low-melting point heat-transfer medium from oxidizing. The device includes a heat sink, a low-melting-point alloy disposed on the heat sink, and an oxidization-proof layer made of a condensable material, disposed on the heat sink, and surrounding the low-melting-point alloy.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is an exploded view of the present invention;

FIG. 2 is an assembled view of the present invention;

FIG. 3 is a cross-sectional view of the present invention; and

FIG. 4 is a cross-sectional view of the present invention when in use.

### DETAILED DESCRIPTION OF PREFERRED EMBODIMENTS

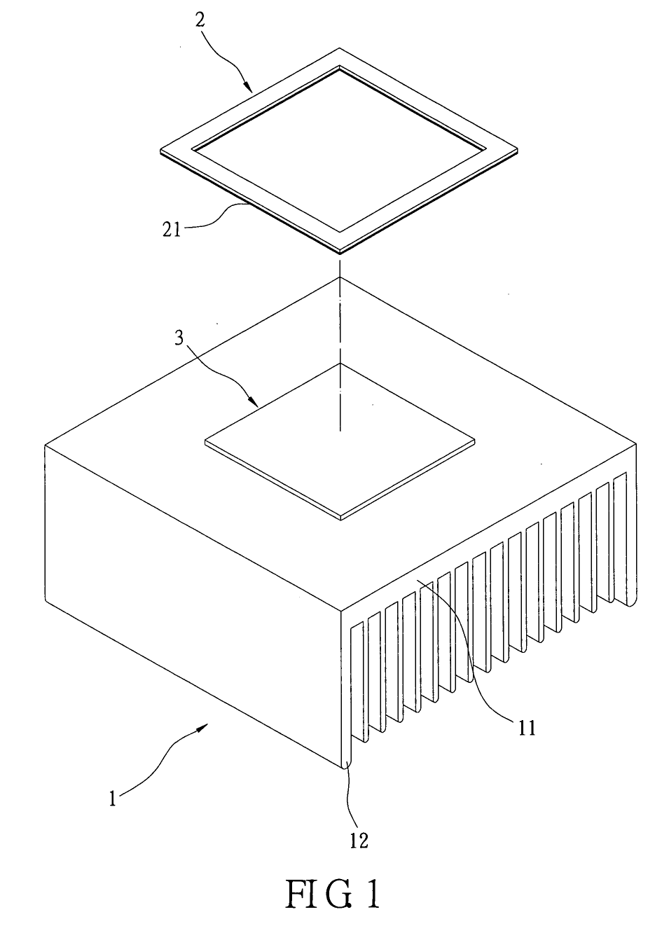

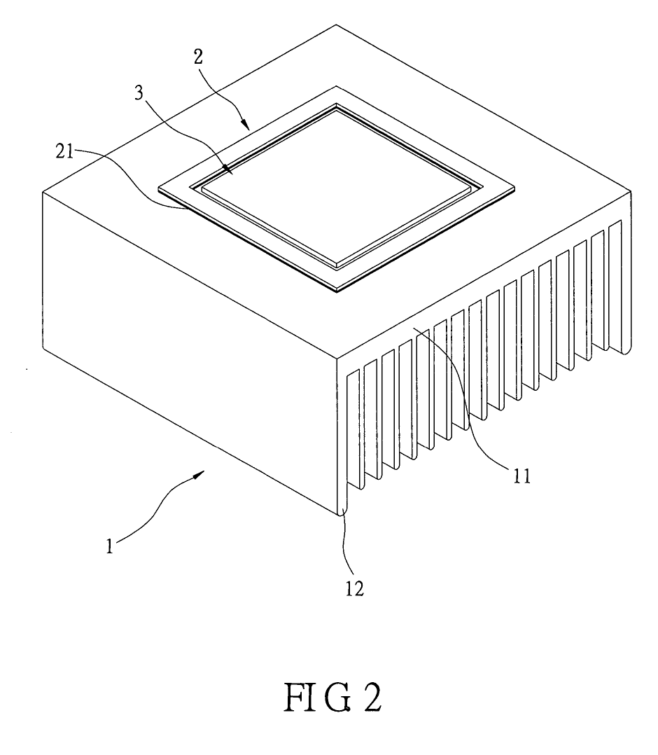

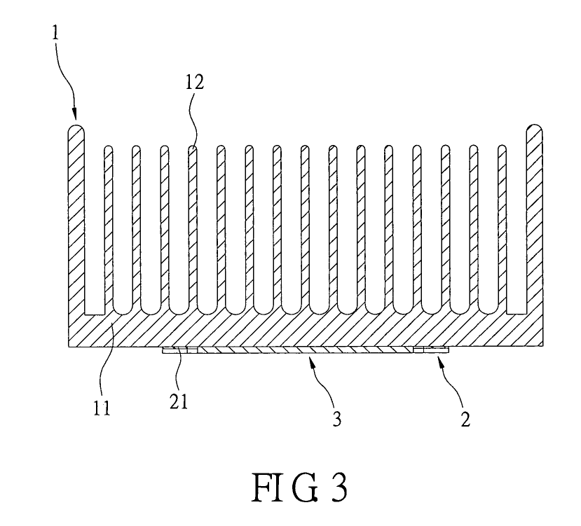

Reference is made to FIGS. 1-4. The present invention provides an oxidization-proof device. It includes a heat sink 1, an oxidization-proof layer 2, and a low-malting-point alloy 3. The heat sink 1 is made of copper or aluminum, which has a good heat-transfer property. The shape or structure of the heat sink 1 is not limited. The heat sink 1 can be any type of heat sink. In this embodiment, the heat sink 1 has a base 11 and multiple fins 12. The fins 12 project from the base 11 and are formed on the base 11 as integral parts. In practice, the fins 12 can also be formed as a separate component and are attached to the base 11 when in use.

The oxidization-proof layer 2 is disposed on a bottom of the base 11 of the heat sink 1. The oxidization-proof layer 2 can be made of a condensable material. The top and bottom of the oxidization-proof layer 2 are kept as flat as possible. The oxidization-proof layer 2 is disposed on the heat sink 1 via attachment. In this embodiment, the oxidization-proof layer 2 is made of condensable foam. The oxidization-proof layer 2 is attached to the bottom of the base 11 of the heat sink 1 via glue 21. The shape of the oxidization-proof layer 2 can be rectangular or circular. The shape of the oxidization-proof layer 2 is not limited in the present invention. The material of the oxidization-proof layer 2 is also not limited and can be made of thick thermal grease that is condensable. Since the thermal grease can be used for heat transfer, it can enhance the heat transfer from the heat source 4 to the heat sink 1. The overall heat-dissipation efficiency is thus improved.

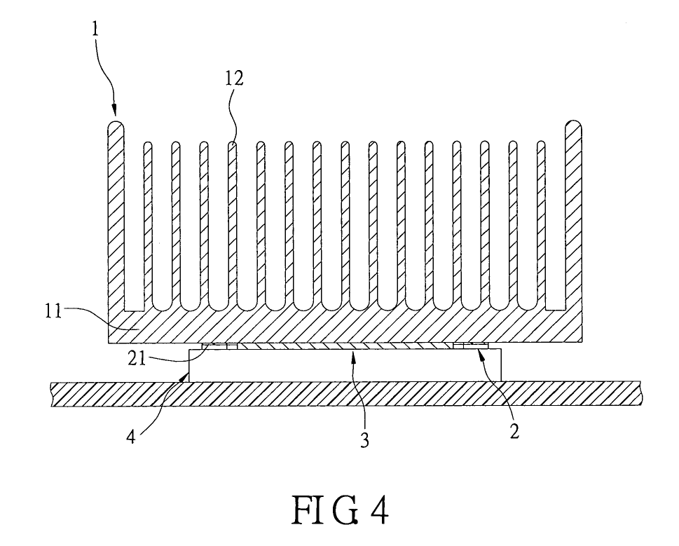

Reference is made to FIG. 4. The low-melting-point alloy 3 is provided on the base 11 of the heat sink 11 and surrounded by the oxidization-proof layer 2. In this way, the invasion of ambient air into the low-melting-point alloy 3 is prevented. The low-melting-point alloy 3 serves as a heat-transfer medium and contacts a heat source 4, such as a chip or a CPU. By using the low-melting-point alloy 3, heat generated by the heat source 4 can be effectively passed to the heat sink 1. Hence, the heat-dissipation efficiency is high.

As described above, the present invention disposes an oxidization-proof layer 2 on the bottom of the heat sink 1. The oxidization-proof layer 2 surrounds the low-melting-point alloy 3, which is disposed between the heat sink 1 and the heat source 4. The oxidization-proof layer 2 can effectively prevent the low-melting-point alloy 3 from invasion by ambient air by isolating the low-melting-point alloy 3 from the ambient air. Hence, ambient air cannot invade the low-melting-point alloy 3 and the oxidization of the low-melting-point alloy 3 is prevented. Thus, by using the present invention, the high heat-transfer efficiency of the low-melting-point alloy 3 is kept.

The oxidization-proof layer 2 is made of a condensable material and hence is condensable. When the low-melting-point alloy 3 becomes a liquid and flows out from the original position, the thickness of the low-melting-point alloy 3 is lowered. Since the oxidization-proof layer 2 is condensable, its thickness can be adjusted according to the thickness of the low-melting-point alloy 3. In this way, the heat sink 1, the low-melting-point alloy 3, and the heat source 4 can be kept in tight contact with each other.

Furthermore, since the oxidization-proof layer 2 surrounds the low-melting-point alloy 3, it can provide a blocking function. When the temperature of the heat source 4 is higher than the low-melting-point alloy 3, the oxidization-proof layer 2 can prevent the low-melting-point alloy 3 from leaking.

Moreover, since the oxidization-proof layer 2 is made of a condensable material, it can serve as a buffer and keep the heat source 4, such as chips or CPUs, from being over-pressed.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. An oxidization-proof device, comprising:
a heat sink;
a low-melting-point alloy disposed on the heat sink; and
an oxidization-proof layer made of a condensable material, disposed on the heat sink, and surrounding the low-melting-point alloy.

2. The oxidization-proof device as claimed in claim 1, wherein the heat sink has a base and multiple fins projecting from the base, and the oxidization-proof layer is disposed on a bottom of the base of the heat sink.

3. The oxidization-proof device as claimed in claim 1, wherein the oxidization-proof layer is made of foam.

4. The oxidization-proof device as claimed in claim 1, wherein the oxidization-proof layer is made of thermal grease.

5. The oxidization-proof device as claimed in claim 1, wherein the oxidization-proof layer is attached to the heat sink by glue.
